(19) United States
(12) Patent Application Publication
(10) Pub. No.: US 2019/0229140 A1
(43) Pub. Date: Jul. 25, 2019

(54) IMAGE SENSOR AND METHOD FOR MANUFACTURING IMAGE SENSOR

(71) Applicant: HUAIAN IMAGING DEVICE MANUFACTURING CORPORATION, Huaian (CN)

(72) Inventors: Tatsuya NAITO, Huaian (CN); Xiaolu Huang, Huaian (CN)

(73) Assignee: HUAIAN IMAGING DEVICE MANUFACTURER CORPORATION, Huaian (CN)

(21) Appl. No.: 16/010,387

(22) Filed: Jun. 15, 2018

(30) Foreign Application Priority Data
Jan. 24, 2018 (CN) 201810065919.7

(51) Int. Cl. H01L 27/146

(52) U.S. Cl. CPC H01L 27/14621; H01L 27/14627; H01L 27/1463; H01L 27/14685; H01L 27/14629

(57) ABSTRACT

An image sensor comprises: a plurality of pixel units, wherein the pixel unit comprises: a photodiode; an optical portion for optically processing light incident to the pixel unit, wherein the optical portion is located above the photodiode and overlaps with the photodiode in a plan view parallel to a main surface of the image sensor; and a gap for preventing light incident to the pixel unit from entering other pixel units, wherein the gap is located around the optical portion in the plan view.

### CROSS-REFERENCE TO RELATED APPLICATIONS

This application claims priority to Chinese Patent Application No. 201810065919.7, filed on Jan. 24, 2018, which is hereby incorporated by reference in its entirety.

### TECHNICAL FIELD

The present disclosure relates generally to the field of semiconductor technology, and more particularly, to an image sensor and a method for manufacturing an image sensor.

### BACKGROUND

In image sensors, there may be optical crosstalk between pixel units.

Accordingly, there is a need for new technologies.

### SUMMARY

One of aims of the present disclosure is to provide a new image sensor and a new method for manufacturing an image sensor.

One aspect of this disclosure is to provide an image sensor, comprising a plurality of pixel units, wherein the pixel unit comprises: a photodiode; an optical portion for optically processing light incident to the pixel unit, wherein the optical portion is located above the photodiode and overlaps with the photodiode in a plan view parallel to a main surface of the image sensor; and a gap for preventing light incident to the pixel unit from entering other pixel units, wherein the gap is located around the optical portion in the plan view.

Another aspect of this disclosure is to provide a method for manufacturing an image sensor, the method comprising: forming an optical layer above a semiconductor substrate in which a photodiode is formed, wherein the optical layer optically processes light incident to the image sensor; and patterning the optical layer so as to form a gap in the optical layer, wherein the gap extends in a direction perpendicular to a main surface of the image sensor and overlaps with an electrical isolation region around the photodiode in a plan view parallel to the main surface, wherein the electrical isolation region is used for preventing charge carriers in the pixel unit from entering other pixel units, wherein, the optical layer patterned forms an optical portion which overlaps with the photodiode in the plan view; and the gap prevents light incident to the pixel unit from entering other pixel units.

Another aspect of this disclosure is to provide a method for manufacturing an image sensor, the method comprising: forming a plurality of optical portions above a semiconductor substrate in which a plurality of photodiodes is formed, wherein the plurality of optical portions optically process light respectively incident to a plurality of pixel units, there is a gap located between neighboring optical portions, and the gap prevents light incident to the pixel unit from entering other pixel units, wherein the gap: extends in a direction perpendicular to a main surface of the image sensor; and overlaps with an electrical isolation region around a photodiode in the pixel unit in a plan view parallel to the main surface.

Further features of the present disclosure and advantages thereof will become apparent from the following detailed description of exemplary embodiments with reference to the attached drawings.

### BRIEF DESCRIPTION OF THE DRAWINGS

The accompanying drawings, which constitute a part of the specification, illustrate embodiments of the present disclosure and, together with the description, serve to explain the principles of the present disclosure.

The present disclosure will be better understood according the following detailed description with reference of the accompanying drawings.

FIG. 1 schematically illustrates a configuration of an image sensor according to one or more exemplary embodiments of this disclosure.

FIGS. 2a and 2b schematically illustrates light paths in FIG. 1.

FIG. 3 schematically illustrates a configuration of an image sensor according to one or more exemplary embodiments of this disclosure.

FIGS. 4a and 4b schematically illustrates light paths in FIG. 3.

FIG. 5 schematically illustrates a configuration of an image sensor according to one or more exemplary embodiments of this disclosure.

FIG. 6 schematically illustrates a configuration of an image sensor according to one or more exemplary embodiments of this disclosure.

FIG. 7 schematically illustrates a configuration of an image sensor according to one or more exemplary embodiments of this disclosure.

FIG. 8 schematically illustrates a configuration of an image sensor according to one or more exemplary embodiments of this disclosure.

FIG. 9 schematically illustrates a configuration of an image sensor according to one or more exemplary embodiments of this disclosure.

FIG. 10 schematically illustrates a configuration of an image sensor according to one or more exemplary embodiments of this disclosure.

FIGS. 11 to 13 schematically illustrate respectively a method for manufacturing an image sensor according to one or more exemplary embodiments of this disclosure, in fragmentary cross sections of the image sensor at one or more steps.

Note that, in the embodiments described below, in some cases the same portions or portions having similar functions are denoted by the same reference numerals in different drawings, and description of such portions is not repeated. In some cases, similar reference numerals and letters are used to refer to similar items, and thus once an item is defined in one figure, it need not be further discussed for following figures.

In order to facilitate understanding, the position, the size, the range, or the like of each structure illustrated in the accompanying drawings and the like are not accurately represented in some cases. Thus, the disclosure is not necessarily limited to the position, size, range, or the like as disclosed in the accompanying drawings and the like.

### DETAILED DESCRIPTION

Various exemplary embodiments of the present disclosure will be described in details with reference to the accompanying drawings in the following. It should be noted that the relative arrangement of the components and steps, the numerical expressions, and numerical values set forth in these embodiments do not limit the scope of the present disclosure unless it is specifically stated otherwise.

The following description of at least one exemplary embodiment is merely illustrative in nature and is in no way intended to limit this disclosure, its application, or uses. That is to say, the structure and method discussed herein are illustrated by way of example to explain different embodiments according to the present disclosure. It should be understood by those skilled in the art that, these examples, while indicating the implementations of the present disclosure, are given by way of illustration only, but not in an exhaustive way. In addition, the accompanying drawings are not necessarily drawn to scale, and some features may be enlarged to show details of some specific components.

Techniques, methods and apparatus as known by one of ordinary skill in the relevant art may not be discussed in detail, but are intended to be regarded as a part of the specification where appropriate.

In all of the examples as illustrated and discussed herein, any specific values should be interpreted to be illustrative only and non-limiting. Thus, other examples of the exemplary embodiments could have different values.

In accordance with some exemplary embodiments of the present disclosure, an image sensor is provided.

In some embodiments, an image sensor according to one or more exemplary embodiments of this disclosure comprises a photodiode 10, an optical portion 20, and a gap 30. The optical portion 20 is located above the photodiode 10, and overlaps with the photodiode 10 in a plan view parallel to a main surface of the image sensor. Although the optical portion 20 and the photodiode 10 completely overlap in the plan view in the illustrative example shown in the accompanying drawings, those skilled in the art may appreciate that the overlap of the optical portion 20 and the photodiode 10 in the plan view in the present disclosure may be complete or partial overlap, and the area of the optical portion 20 and that of the photodiode 10 in the plan view may also be different. The optical portion 20 is used to optically process light incident to the photodiode 10. The optically processing includes changing the light transmission path, filtering the light, and the like.

The gap 30 is located around the optical portion 20, and overlaps with an electrical isolation region 40 around the photodiode 10 in a plan view parallel to the main surface of the image sensor. The electrical isolation region 40 is used for preventing charge carriers in the photodiode 10 of the pixel unit from entering the photodiode 10 of other pixel units. Although the gap 30 and the electrical isolation region 40 completely overlap in the plan view in the illustrative example shown in the accompanying drawings, those skilled in the art may appreciate that the overlap of the gap 30 and the electrical isolation region 40 in the plan view may be complete or partial overlap, and the area of the gap 30 and that of the electrical isolation region 40 in the plan view may also be different.

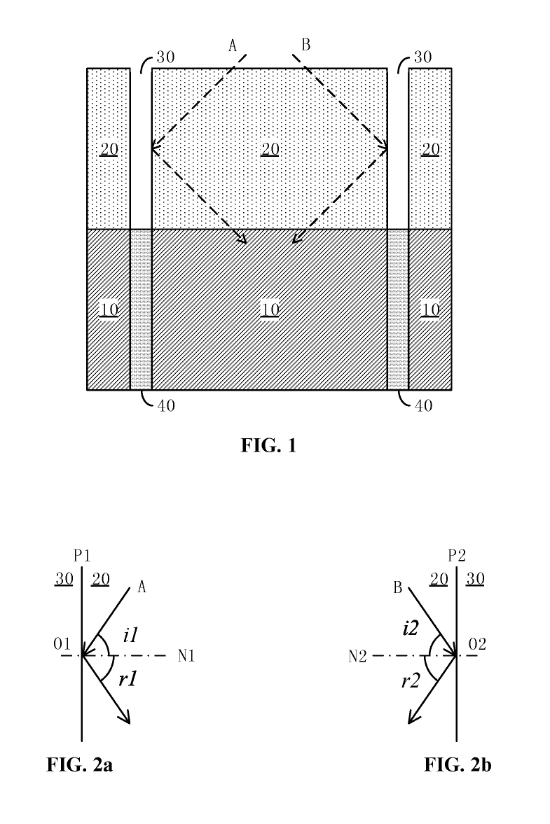

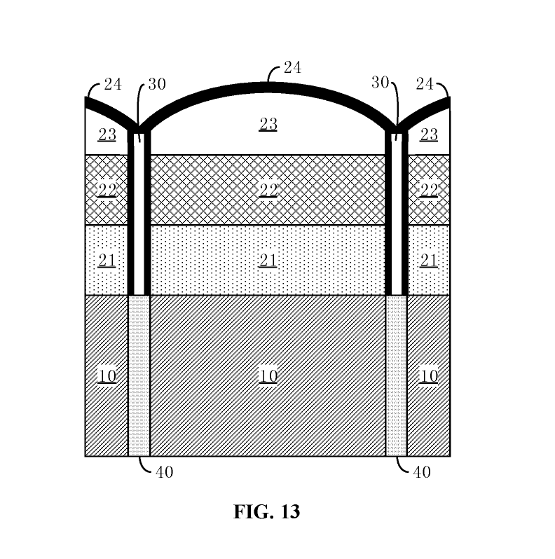

The gap 30 is configured to prevent light incident to the pixel unit from entering other pixel units, that is, to prevent incident light to the current photodiode 10 from entering adjacent photodiode 10. There is no solid or liquid filler in an interior of the gap 30, i.e., the gap 30 is vacuum or filled with gas. For example, the gas may be a gas in a processing environment (e.g., an operating chamber) during manufacturing an image sensor, or a gas in a working or using environment of an image sensor. The top of the gap 30 may be open (as shown in FIGS. 1, 3, 5 to 10) or may be closed (as shown in FIG. 13). The top of the gap 30 is not limited in the disclosure, as long as the interior of the gap 30 is vacuum or filled with gas. The vacuum gap has a refractive index of 1, and the refractive index of air or a common gas is very close to 1. Therefore, the refractive index of the gap 30 is represented by 1 in the description herein.

Since the refractive index of the optical portion 20 is higher than the refractive index of the gap 30, when light (e.g., the light schematically shown by the dashed lines with arrows A and B in FIG. 1) transmits from the optical portion 20 to the gap 30 (being possible into the adjacent photodiode 10 thereby), i.e., from an optically denser medium to an optically thinner medium, a total reflection may occur at an interface between the optical portion 20 and the gap 30 if an incident angle of the light is wider than a critical angle. Thus, the light may not continue to travel into the gap 30 but be reflected back into the optical portion 20, so that the light may not enter the adjacent photodiode 10, as shown in FIG. 1.

Light paths of preventing light incident to the pixel unit from entering other pixel units by the gap 30 are shown in FIGS. 2a and 2b. Referring to FIG. 2a, the line P1 schematically represents the interface between the optical portion 20 and the gap 30 on the left side in FIG. 1. The light A reaches the interface P1 at the point O1, the normal at the point O1 is the line N1, the incident angle of the light A is the angle i1, and the reflective angle of the light A is the angle r1. The light A travels toward the interface P1 in the optical portion 20, attempting to enter the gap 30 so as to enter the adjacent photodiode 10. If the refractive index of the optical portion 20 on the right side of the interface P1 is n1, the refractive index of the gap 30 on the left side of the interface P1 is n2, then the critical angle θc at which the total reflection occurs is calculated by

$$θ c = arc sin ( \frac{n 2}{n 1} )$$

according to Snell's Law. If the incident angle it of the light A is wider than the critical angle θc, then the light A will not enter the gap 30 instead of being totally reflected by the interface P1 and returning to the optical portion 20, and will finally enter the current photodiode 10 without entering other adjacent photodiodes 10. Referring to FIG. 2b, the line P2 schematically represents the interface between the optical portion 20 and the gap 30 on the right side in FIG. 1. The light B reaches the interface P2 at the point O2, the normal at the point O2 is the line N2, the incident angle of the light B is the angle i2, and the reflective angle of the light B is the angle r2. Since the light path shown in FIG. 2b is similar to that in FIG. 2a, the description thereof is omitted.

The critical angle

$$θ c = arc sin ( \frac{n 2}{n 1} )$$

at which the total reflection occurs when light transmits from the optical portion 20 to the gap 30, wherein n1 is the refractive index of the optical portion 20, and n2 is the refractive index of the gap 30. As described above, the refractive index n2 of the gap 30 is 1, thus appropriately adjusting the refractive index n1 of the optical portion 20, for example, making the refractive index n1 of the optical portion 20 as high as possible within a suitable range, may obtain a critical angle θc as small as possible. Thus, most of the light may be reflected back into the optical portion 20 arriving at the interface between the optical portion 20 and the gap section 30, so as to achieve the technical effect of suppressing optical crosstalk as well as possible.

In practical application, the refractive index n1 of the optical portion 20 (such as a filter 21, an intermediate layer 22, and a microlens 23 described later, etc.) is usually in an approximate range of 1.5 to 1.8. According to the above formula

$$θ c = arc sin ( \frac{n 2}{n 1} ) ,$$

the critical angle θc calculated is approximately in the range of 33.7 degrees to 41.8 degrees. Since the incident light enters the optical portion 20 only from the top of the image sensor, the incident light at the interface between the optical portion 20 and the gap section 30 comes from right above or obliquely above. Therefore, the incident angle of most of the light is wider than the critical angle θc. However, those skilled in the art may further increase (for example, changing the material of the optical portion 20 or doping impurities, etc.) the refractive index n1 of the optical portion 20 within an appropriate range to further reduce the critical angle θc, in order to achieve better technical effects.

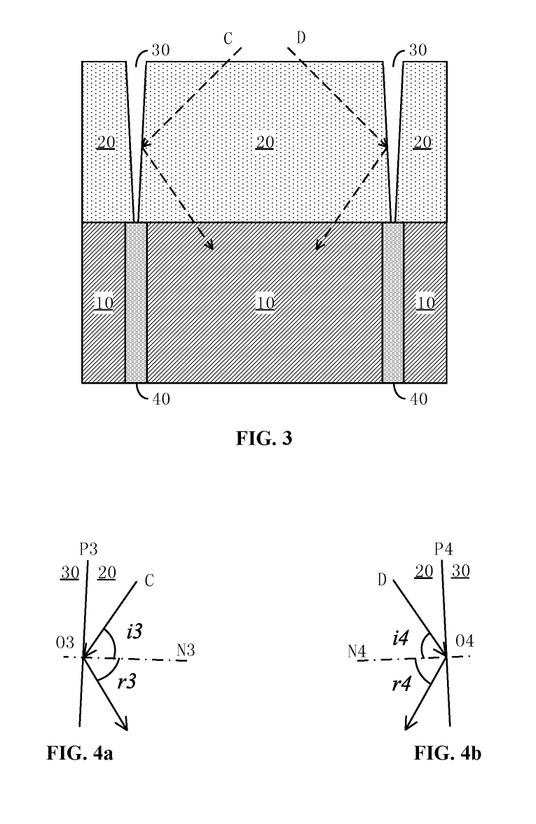

The gap 30 of the image sensor in the present disclosure extends along the sidewall of the optical portion 20 and in a direction perpendicular to the main surface of the image sensor. In some embodiments, as shown in FIG. 1, the sidewall of the gap 30 is perpendicular or substantially perpendicular to the main surface of the image sensor. In some embodiments, as shown in FIG. 3, the sidewall of the gap 30 has a slope, the sloping direction of the slope makes the size of the bottom of the gap 30 is smaller than the size of the top of the gap 30. In this way, as compared with the structure shown in FIG. 1, if the travelling direction of the light in the optical portion 20 is the same, the incident angle (i.e., the angle between the incident light and the normal line) when the light reaches the interface between the optical portion 20 and the gap 30 is increased, which is more conducive to occurring of total reflection and then further suppressing optical crosstalk. Those skilled in the art may appreciate, the sloping sidewall of the gap 30 shown in FIG. 3 only intends to schematically illustrate the sloping direction (i.e., sloping toward the center of the gap 30 from top to bottom) of the sidewall of the gap 30 rather than to limit the sloping angle of the sidewall.

In these embodiments, the light paths at the interface between the optical portion 20 and the gap 30 are shown in FIGS. 4a and 4b. Referring to FIG. 4a, the line P3 schematically represents the interface between the optical portion 20 and the gap 30 on the left side in FIG. 3, which slopes to the left side from top to bottom. The light C reaches the interface P3 at the point O3, the normal at the point O3 is the line N3, the incident angle of the light C is the angle i3, and the reflective angle of the light C is the angle r3. Since the interface P3 slopes to the left side from top to bottom, the normal line N3 slopes downward from left to right as compared with the normal line N1 shown in FIG. 2a. Therefore, when the travelling direction of the light C is the same as that of the light A, the angle between the light C and the normal line N3 is wider than the angle between the light A and the normal line N1, that is, the incident angle i3 is wider than the incident angle i1. Referring to FIG. 4b, the line P4 schematically represents the interface between the optical portion 20 and the gap 30 on the left side in FIG. 3, which slopes to the right side from top to bottom. The light D reaches the interface P4 at the point O4, the normal at the point O4 is the line N4, the incident angle of the light D is the angle i4, and the reflective angle of the light D is the angle r4. Since the interface P4 slopes to the right side from top to bottom, the normal line N4 slopes downward from right to left as compared with the normal line N2 shown in FIG. 2b. Therefore, when the travelling direction of the light D is the same as that of the light B, the angle between the light D and the normal line N4 is wider than the angle between the light B and the normal line N2, that is, the incident angle i4 is wider than the incident angle i2. Therefore, in these embodiments, the slope of the sidewall of the gap 30 increases the probability of the incident angle of incident light wider than the critical angle, that is, the probability of occurring of total reflection, and further reduces the probability of occurring of optical crosstalk among the photodiodes.

In some embodiments, the bottom of the gap 30 is lower than or level with the bottom of the optical portion 20. As compared with the case where the bottom of the gap 30 is higher than the bottom of the optical portion 20, i.e., the case where the depth of the gap 30 is less than the depth of the optical portion 20, the sidewall of the optical portion 20 in the image sensor according to these embodiments is capable of reflecting light over its entire depth range.

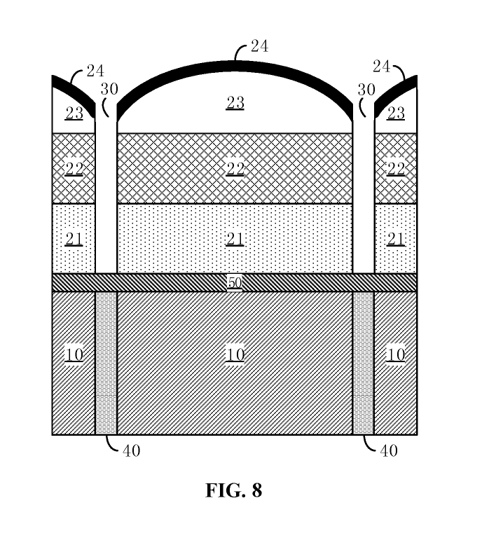

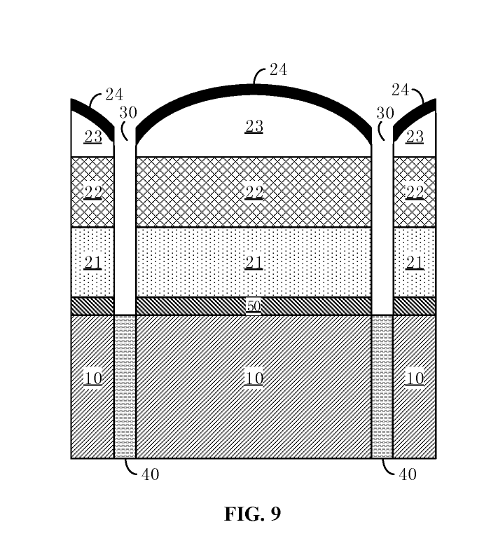

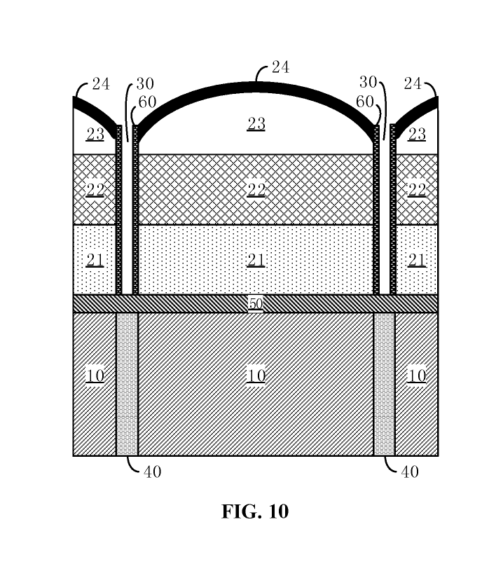

In some embodiments, the image sensor of the present disclosure further comprises a spacer layer 50 (see FIGS. 8 to 10) located between the photodiode 10 and the optical portion 20. The spacer layer 50 may be a layer serving any suitable function, for example, the spacer layer 50 may be a planarizing layer, a passivation layer, an anti-reflection layer, and/or a high-k dielectric layer, etc. In some embodiments, the bottom of the gap 30 is lower than or level with the bottom of the spacer layer 50 as shown in FIG. 9. Thus, it is possible that the sidewall of the spacer layer 50 is capable of reflecting light over its entire depth range, so that the light travelled through the optical portion 20 may not pass through the spacer layer 50 and then into an adjacent photodiode 10.

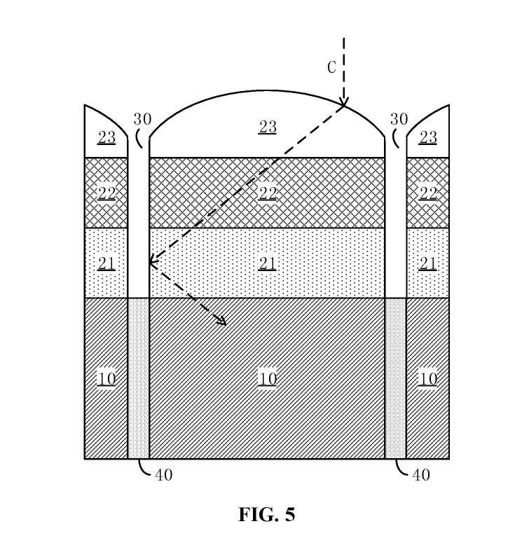

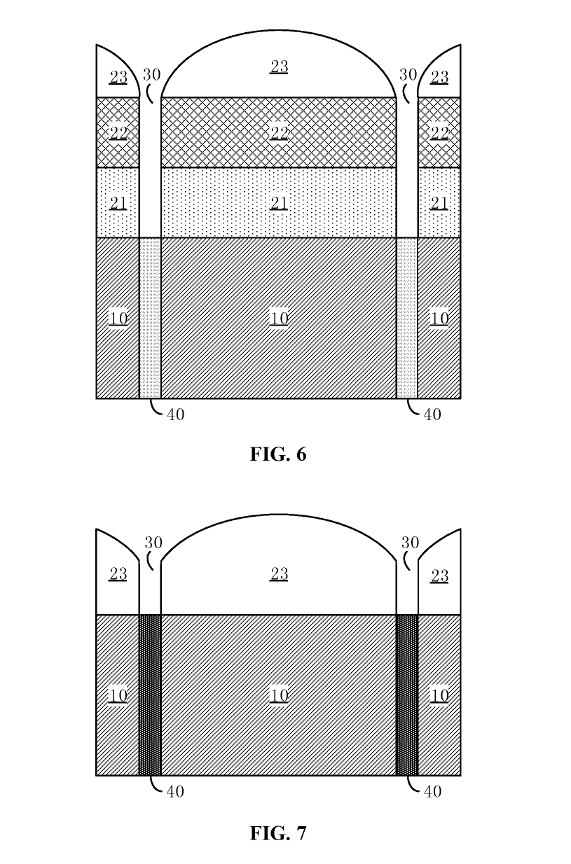

In some embodiments, as shown in FIGS. 5, 6, 8 to 13, the optical portion 20 comprises a microlens 23, a filter 21, and an intermediate layer 22 located between the microlens 23 and the filter 21. The microlens 23 is used for gathering incident light, the filter 21 is used for filtering the light (for example, filtering the light having one or more specific wavelengths), and the intermediate layer 22 may be, for example, a filler layer or the like. In the illustrative example shown in FIG. 5, the gap 30 extends along the sidewall of the micro-lens 23, the intermediate layer 22 and the filter 21 and extends in a direction perpendicular to the main surface of the image sensor (referred as a vertical direction hereafter), so that each of the microlens 23, the intermediate layer 22 and the filter 21 has one or more sidewall capable of reflecting light.

In the illustrative example shown in FIG. 6, the gap 30 extends along the sidewall of the intermediate layer 22 and the filter 21 and extends in the vertical direction, but the microlens 23 are formed between neighboring gaps 30 and there is no interface between the gap 30 and the microlens 23. In these cases, only the intermediate layer 22 and the filter 21 have sidewalls capable of reflecting light, but the microlens 23 does not. However, the illustrative example may still achieve the technical effect in the present disclosure of suppressing optical crosstalk.

In the illustrative example shown in FIG. 7, the image sensor does not have a filter 21, and thus does not have an intermediate layer 22 between the filter 21 and the microlens 23. In these cases, the gap 30 extends only along the sidewall of the microlens 23 in the vertical direction, the sidewall (i.e., the interface between the microlens 23 and the gap 30) of the microlens 23 is thus capable of reflecting light, thereby suppressing optical crosstalk.

In some embodiments, as shown in FIGS. 8 to 10, the optical portion 20 further comprises an anti-reflection layer 24 located in an upper portion of the optical portion 20. In these embodiments, the gap 30 extends not only along the sidewall of other portions (comprising the microlens 23, the intermediate layer 22, and the filter 21, etc.) of the optical portion 20 but also along the sidewall of the anti-reflection layer 24 of the optical portion 20 in the vertical direction. The sidewalls of the reflective layer 24 and the other portions of the optical portion 20 are both capable of reflecting light. Although the other portions of the optical portion 20 in the image sensor shown in FIGS. 8 to 10 comprise the microlens 23, the intermediate layer 22, and the filter 21, those skilled in the art may appreciate that the other portions of the optical portion 20 may comprise more or less elements or structures than those shown in the figures, and those skilled in the art may make selection based on practical applications.

In some embodiments, the image sensor further comprises a reflection layer 60 on a sidewall of the optical portion 20, as shown in FIG. 10. The reflection layer 60 is used to reflect light reaching the surface of the reflection layer 60. In these embodiments, the optical portion 20 comprises the filter 21, the intermediate layer 22, the microlens 23, and the anti-reflection layer 24 as shown in FIG. 10. Part of light travelling through the sidewall of the optical portion 20 and reaching the surface of the reflection layer 60 is reflected by the reflection layer 60 back into the optical portion 20, and then reaches into the current photodiode 10, while the other part of the light reaching the surface of the reflection layer 60 may pass through the surface of the reflection layer 60 and continue to travel in the reflection layer 60. When the light reaches the interface between the reflection layer 60 and the gap 30, a total reflection may occur since the refractive index of the reflection layer 60 in solid state is higher than the refractive index of the gap 30, so that the light may be reflected back into the optical portion 20 and then reach the current photodiode 10. Thus, optical crosstalk caused by the incident light to the current photodiode 10 entering other photodiodes 10 may be avoided.

Appropriately selecting the refractive index of the material forming the reflection layer 60 may make most of the light be reflected back into the optical portion 20 when reaching the surface of the reflection layer 60. Appropriately selecting the refractive index of the material forming the reflection layer 60, the critical angle at which the total reflection may occur at the interface between the reflection layer 60 and the gap 30 may be narrowed as much as possible. Thus, a part of the light passing through the surface of the reflection layer 60 and travelling in the reflection layer 60 may be reflected back into the optical portion 20 as much as possible when reaching the interface between the reflection layer 60 and the gap 30, so as to achieve the technical effect of suppressing optical crosstalk as much as possible.

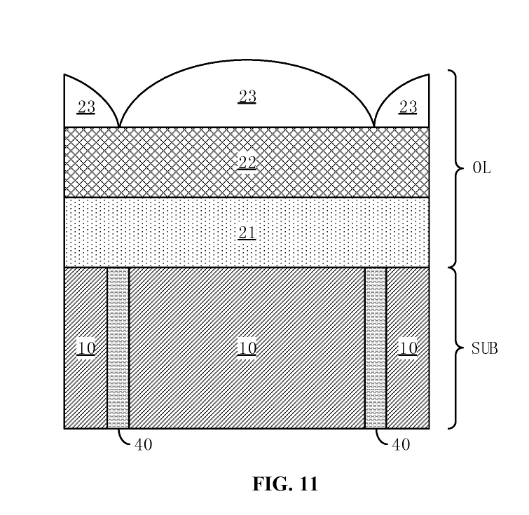

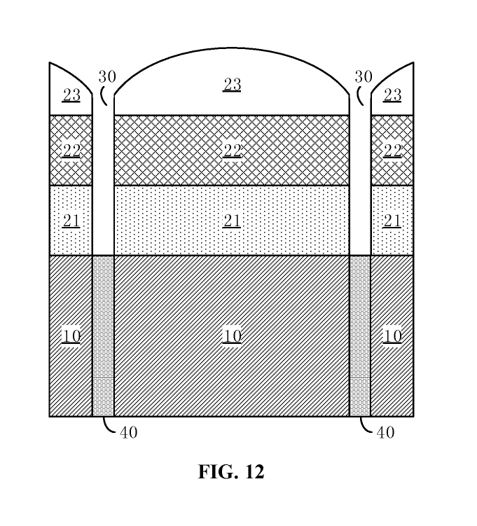

A method for manufacturing an image sensor according to some embodiments of the present disclosure is described below with reference to FIGS. 11 and 12. In these embodiments, the method for manufacturing an image sensor comprises the following steps.

As shown in FIG. 11, forming an optical layer 21 above a semiconductor substrate 10 in which a photodiode 10 is formed, wherein the optical layer 21 optically processes light incident to the image sensor.

As shown in FIG. 12, patterning the optical layer 21 so as to form a gap 30 extending in a direction perpendicular to a main surface of the image sensor, wherein the gap 30 overlaps with an electrical isolation region 40 around the photodiode 10 in a plan view parallel to the main surface. The patterned optical layer 21 forms an optical portion 20 which overlaps with the photodiode 10 in the plan view. The gap 30 is used for preventing light incident to the pixel unit from entering other pixel units.

In the method for manufacturing an image sensor according to these embodiments of the present disclosure as shown in FIGS. 10 and 11, forming the optical layer 21 above the semiconductor substrate 10 comprises: forming a filter layer above the semiconductor substrate 10, wherein the filter layer is used for forming filters 21 through a patterning process; forming an intermediate layer (used for forming the intermediate layer 22) above the filter layer; and forming a microlens layer above the intermediate layer, wherein the microlens layer is used for forming microlenses 23 through a patterning process. The optical portion 20 formed in the image sensor comprises a microlens 23, a filter 21, and an intermediate layer 22 between the microlens 23 and the filter 21. The microlens 23 is used for gathering the incident light, the filter 21 is used for filtering the light (for example, filtering the light having one or more specific wavelengths), and the intermediate layer 22 may be a filler layer or the like, for example.

The gap 30 formed extends along the sidewall of the optical portion 20 in a vertical direction, for preventing light incident to the pixel unit from entering other pixel units, that is, optically isolating light incident to the current photodiode 10 from the adjacent photodiode 10. The gap 30 is formed as vacuum gap or a gap filled with gas, and its refractive index is 1. The optical part 20 is a solid, and has a refractive index higher than 1. Thus, when the light reaches the interface between the optical portion 20 and the gap 30 from the interior of the optical portion 20, a total reflection may occur if the incident angle is wider than the critical angle, so that the light may be reflected back into the optical portion 20 not to enter the adjacent photodiode 10.

In some embodiments, controlling the process for forming the gap 30, for example controlling the position where the etching stops (e.g., by controlling the time of etching, or by using stop etching layer, etc.), make the bottom of the gap 30 is lower than or level with the bottom of the optical layer 21. Thus, the sidewall of the optical portion 20 is capable of reflecting light over its entire depth range.

In some embodiments, for example, in the cases that there is a spacer layer 50 located between the optical portion 20 and the semiconductor substrate 10 as shown in FIGS. 8 to 10, forming an optical layer 21 above a semiconductor substrate 10 in the above method comprises: forming a spacer layer 50 above the semiconductor substrate 10; and forming the optical layer 21 above the spacer layer 50. The spacer layer 50 may be a layer serving any suitable function, for example, the spacer layer 50 may be a planarizing layer, a passivation layer, an anti-reflection layer, and/or a high-k dielectric layer, etc. In some embodiments, the bottom of the gap 30 is higher than the bottom of the spacer layer 50 as shown in FIGS. 8 and 10, or a part of the gap 30 may be formed by etching a part (e.g., upper part) of the spacer layer 50 (not shown). Thus, entire or part of the spacer layer 50 may be retained under the gap 30, so that the spacer layer 50 may serve its function under the gap 30. In some embodiments, the bottom of the gap 30 level with the bottom of the spacer layer 50 as shown in FIG. 9, or is lower than the bottom of the spacer layer 50 (not shown). In these cases, a part of the gap 30 may be formed by etching a part (e.g., upper part in an electrical isolation region around the photodiode) of the semiconductor substrate 10. Thus, it is possible that the sidewall of the spacer layer 50 is capable of reflecting light over its entire depth range, so that the light travelled through the optical portion 20 may not pass through the spacer layer 50 and then into an adjacent photodiode 10.

In some embodiments, the optical portion 20 formed through the method for manufacturing an image sensor is shown in FIG. 3. In these embodiments, the sidewall of the gap 30 in the image sensor has a slope, which has a sloping direction as shown in FIG. 3, such that the size of the bottom of the gap 30 is smaller than the size of the top of the gap 30. In this way, as compared with the structure in which the gap 30 has vertical sidewalls, if the travelling direction of the light in the optical portion 20 is the same, the incident angle at the interface between the optical portion 20 and the gap 30 is increased, which is more conducive to occurring of total reflection and then further suppressing optical crosstalk. Such a structure with sloping sidewalls may be formed by controlling the slope in the etching process the optical layer 21 to form the gap 30 with sloping sidewalls.

In some embodiments, the optical portion 20 in the image sensor formed by the method for manufacturing an image sensor of the present disclosure is shown in FIGS. 8 to 10. In these embodiments, forming the optical layer 21 above the semiconductor substrate 10 comprises: forming a filter layer above the semiconductor substrate 10, wherein the filter layer is used for forming filters 21 through a patterning process; forming an intermediate layer (used for forming the intermediate layer 22) above the filter layer; forming a microlens layer above the intermediate layer, wherein the microlens layer is used for forming microlenses 23 through a patterning process; and forming an anti-reflection layer (used for forming the anti-reflection layer 24) above the microlens layer. After forming the optical layer 21, patterning (for example by lithographic process and etching process) the entire optical layer 21 to form grooves above the electrical isolation regions 40 around the photodiodes 10. Thus, the portion of the optical layer 21 located between the neighboring grooves is formed as the optical portions 20, and the grooves located between the neighboring optical portions 20 is formed as the gaps 30. In these embodiments, the gap 30 in the image sensor formed by the method of the present disclosure extends in the vertical direction not only along the sidewall of other portions of the optical portion 20 (e.g., the microlens 23, the intermediate layer 22, and the filter 21, etc.) but also along the sidewall of the anti-reflection layer 24. Therefore, the anti-reflection layer 24 and other portions of the optical portion 20 both have sidewalls capable of reflecting light.

In some embodiments, the method for manufacturing an image sensor of the present disclosure may comprise forming (e.g., by deposition processing) an anti-reflection layer 24 on a patterned optical layer 21, as shown in FIG. 13. Since the anti-reflection layer 24 is formed above the upper portion of the optical portion 20 after patterning the optical layer 21, that is, the anti-reflection layer 24 is formed after forming the gap 30, there may be some material forming the anti-reflection layer 24 deposited on the sidewalls of the optical portions 20 (shown as the black portions on the sidewall of the optical portion 20 in FIG. 13) or the bottom of the gap 30 (not shown). The material forming the anti-reflection layer 24 may be silicon oxide, silicon nitride, silicon oxynitride, or the like. The refractive index of these materials typically forming the anti-reflection layer 24, is slightly less than the refractive index of the material forming the optical portion 20, such as the filter 21. For example, the refractive index of the material forming the filter 21 is approximately in the range of 1.5 to 1.8, and the refractive index of the material forming the anti-reflection layer 24 is approximately 1.5. Since total reflection of light may occur at the interface between these materials deposited on the sidewalls of the optical portions 20 and the gap 30, these materials may slightly reduce the technical effect of occurring of total reflection. Even so, since the refractive indexes of these materials are still much higher than the refractive index of the gap 30, the image sensor manufactured according to the method in these embodiments is still capable of achieving the technical effect of the present disclosure.

Nevertheless, in order to avoid the slight reduction of the technical effect occurring in the embodiments described above with reference to FIG. 13, one feasible solution is patterning the optical layer 21 after forming the anti-reflection layer 24 to form the gap 30 as described above. Other feasible solutions are using a low coverage deposition process to form the anti-reflection layer 24, for example, by controlling the width of the gap section 30 (the narrower of the width of the gap section 30, the lower of the coverage to the sidewall of the optical portion 20 and the bottom of the gap section 30), and/or controlling the deposition processing conditions, so as to minimize the material forming the anti-reflection layer 24 deposited on the sidewall of the optical portion 20 and the bottom of the gap 30.

In some embodiments, the method for manufacturing an image sensor of the present disclosure may further comprise forming a reflection layer 60 on the sidewall of the optical portion 20 after forming the gap 30. The image sensor formed through the method according to these embodiments is shown in FIG. 10. The reflection layer 60 is configured to reflect light reaching the surface thereof. In these embodiments, a part of light travelling in the optical portion 20 (comprising the optical filter 21, the intermediate layer 22, the microlens 23, and the anti-reflection layer 24 in these embodiments shown in FIG. 10) through the sidewall of the optical portion 20 and reaching the surface of the reflection layer 60 may be reflected back into the optical portion 20, and then into the current photodiode 10; the other part of the light reaching the reflection layer 60 may pass through the surface of the reflection layer 60 and continue to travel in the reflection layer 60, and be total reflected at the interface between the reflection layer 60 and the gap 30 since the refractive index of the reflection layer 60 in solid state is higher than the refractive index of the gap 30, so that back into the optical portion 20 and then into the current photodiode 10. Thus, avoiding the incident light to the current photodiode 10 from entering adjacent photodiodes 10 to cause optical crosstalk may be achieved.

In some embodiments, a method for manufacturing an image sensor of the present disclosure may form the optical portions 20 spaced apart from each other without forming an optical layer first and then patterning the optical layer to form the optical portions 20. In these embodiments, the method for manufacturing an image sensor may comprises: forming optical portions 20 above a semiconductor substrate 10 in which a photodiode is formed, wherein there is no contact between neighboring the optical portions, i.e., there is a gap 30 between the neighboring optical portions 20. The optical portion 20 optically processes light incident to the image sensor. The gap 30 extends along a sidewall of the optical portion 20 and in a direction perpendicular to a main surface of the image sensor, and overlaps with an electrical isolation region 40 around the photodiode 10 in a plan view parallel to the main surface. The gap 30 prevents light incident to the pixel unit from entering other pixel units. In these embodiments, for example, performing deposition of the material forming the optical portion 20 may be performed after shielding, by photoresist for example, some areas of surface of the semiconductor substrate 10 and removing the shield (e.g., the photoresist) along with the deposed material thereon to form a first group of optical portions 20, and then forming one or more other groups of optical portions 20 through similar approach described above, thereby the optical portions 20 spaced apart from each other are formed without forming an optical layer first and then patterning the optical layer to form the optical portions 20.

Although the sidewalls of the gap 30 in FIGS. 5 to 13 of the present disclosure are vertical sidewalls, those skilled in the art will appreciate that the sidewalls in these embodiments with reference to these figures may be also like the sidewalls show in FIG. 3.

While a structure in a pixel region of each image sensor has been shown in the accompanying drawings of the present disclosure in a form of fragmentary cross sections, an entire structure of each image sensor may be conceivable for those skilled in the art based on the description and accompanying drawings.

A structure capable of reflecting light described in the present disclosure comprises the material of the structure is capable of reflecting light and total reflection may occur at any surface of the structure.

The term “A or B” used through the specification refers to “A and B” and “A or B” rather than meaning that A and B are exclusive, unless otherwise specified.

The terms “front,” “back,” “top,” “bottom,” “over,” “under” and the like, as used herein, if any, are used for descriptive purposes and not necessarily for describing permanent relative positions. It should be understood that such terms are interchangeable under appropriate circumstances such that the embodiments of the disclosure described herein are, for example, capable of operation in other orientations than those illustrated or otherwise described herein.

The term “exemplary”, as used herein, means “serving as an example, instance, or illustration”, rather than as a “model” that would be exactly duplicated. Any implementation described herein as exemplary is not necessarily to be construed as preferred or advantageous over other implementations. Furthermore, there is no intention to be bound by any expressed or implied theory presented in the preceding technical field, background, summary or detailed description.

The term “substantially”, as used herein, is intended to encompass any slight variations due to design or manufacturing imperfections, device or component tolerances, environmental effects and/or other factors. The term “substantially” also allows for variation from a perfect or ideal case due to parasitic effects, noise, and other practical considerations that may be present in an actual implementation.

In addition, the foregoing description may refer to elements or nodes or features being “connected” or “coupled” together. As used herein, unless expressly stated otherwise, “connected” means that one element/node/feature is electrically, mechanically, logically or otherwise directly joined to (or directly communicates with) another element/node/feature. Likewise, unless expressly stated otherwise, “coupled” means that one element/node/feature may be mechanically, electrically, logically or otherwise joined to another element/node/feature in either a direct or indirect manner to permit interaction even though the two features may not be directly connected. That is, “coupled” is intended to encompass both direct and indirect joining of elements or other features, including connection with one or more intervening elements.

In addition, certain terminology, such as the terms “first”, “second” and the like, may also be used in the following description for the purpose of reference only, and thus are not intended to be limiting. For example, the terms “first”, “second” and other such numerical terms referring to structures or elements do not imply a sequence or order unless clearly indicated by the context.

Further, it should be noted that, the terms “comprise”, “include”, “have” and any other variants, as used herein, specify the presence of stated features, integers, steps, operations, elements, and/or components, but do not preclude the presence or addition of one or more other features, integers, steps, operations, elements, components, and/or groups thereof.

In this disclosure, the term “provide” is intended in a broad sense to encompass all ways of obtaining an object, thus the expression “providing an object” includes but is not limited to “purchasing”, “preparing/manufacturing”, “disposing/arranging”, “installing/assembling”, and/or “ordering” the object, or the like.

Furthermore, those skilled in the art will recognize that boundaries between the above described operations are merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments. However, other modifications, variations and alternatives are also possible. The description and accompanying drawings are, accordingly, to be regarded in an illustrative rather than in a restrictive sense.

Although some specific embodiments of the present disclosure have been described in detail with examples, it should be understood by a person skilled in the art that the above examples are only intended to be illustrative but not to limit the scope of the present disclosure. The embodiments disclosed herein can be combined arbitrarily with each other, without departing from the scope and spirit of the present disclosure. It should be understood by a person skilled in the art that the above embodiments can be modified without departing from the scope and spirit of the present disclosure. The scope of the present disclosure is defined by the attached claims.

1. An image sensor, comprising a plurality of pixel units, wherein the pixel unit comprises:
a photodiode;
an optical portion for optically processing light incident to the pixel unit, wherein the optical portion is located above the photodiode and overlaps with the photodiode in a plan view parallel to a main surface of the image sensor; and
a gap for preventing light incident to the pixel unit from entering other pixel units, wherein the gap is located around the optical portion in the plan view.

2. The image sensor according to claim 1, wherein the gap is vacuum or filled with gas.

3. The image sensor according to claim 1, wherein the gap overlaps with an electrical isolation region around the photodiode in the plan view, wherein the electrical isolation region is used for preventing charge carriers in the pixel unit from entering other pixel units.

4. The image sensor according to claim 1, wherein the gap extends in a direction perpendicular to the main surface.

5. The image sensor according to claim 4, wherein the sidewall of the gap has a slope such that the size of the bottom of the gap is smaller than the size of the top of the gap.

6. The image sensor according to claim 1, wherein the bottom of the gap is lower than or level with the bottom of the optical portion.

7. The image sensor according to claim 1, further comprising:
a spacer layer located between the photodiode and the optical portion,
wherein the bottom of the gap is lower than or level with the bottom of the spacer layer.

8. The image sensor according to claim 1, wherein the optical portion comprises a microlens, a filter, and an intermediate layer located between the microlens and the filter.

9. The image sensor according to claim 1, wherein the optical portion further comprises an anti-reflection layer located in an upper portion of the optical portion.

10. The image sensor according to claim 1, further comprising a reflection layer located between a sidewall of the optical portion and the gap.

11. A method for manufacturing the image sensor according to claim 1, the method comprising:
forming an optical layer above a semiconductor substrate in which the photodiode is formed, wherein the optical layer optically processes light incident to the image sensor; and
patterning the optical layer so as to form the gap in the optical layer, wherein the gap extends in a direction perpendicular to the main surface of the image sensor and overlaps with an electrical isolation region around the photodiode in the plan view parallel to the main surface,
wherein the electrical isolation region is used for preventing charge carriers in the pixel unit from entering other pixel units,
wherein,
the optical layer patterned forms the optical portion which overlaps with the photodiode in the plan view; and
the gap prevents light incident to the pixel unit from entering other pixel units.

12. The method according to claim 11, wherein the bottom of the gap is lower than or level with the bottom of the optical layer.

13. The method according to claim 11, wherein forming the optical layer above the semiconductor substrate comprises:
forming a spacer layer above the semiconductor substrate; and
forming the optical layer above the spacer layer,
wherein the bottom of the gap is lower than or level with the bottom of the spacer layer.

14. The method according to claim 11, wherein forming the optical layer above the semiconductor substrate comprises:
forming a filter layer above the semiconductor substrate;
forming an intermediate layer above the filter layer; and
forming a microlens layer above the intermediate layer.

15. The method according to claim 14, wherein forming the optical layer above the semiconductor substrate further comprises:
forming an anti-reflection layer above the microlens layer.

16. The method according to claim 11, further comprising:
forming an anti-reflection layer above the optical layer patterned.

17. The method according to claim 11, further comprising:
forming a reflection layer on a sidewall of the optical portion.

18. A method for manufacturing the image sensor according to claim 1, the method comprising:
forming a plurality of optical portions above a semiconductor substrate in which a plurality of photodiodes is formed, wherein the plurality of optical portions optically process light respectively incident to the plurality of pixel units, there is the gap located between neighboring optical portions, and the gap prevents light incident to the pixel unit from entering other pixel units,
wherein the gap:
extends in a direction perpendicular to the main surface of the image sensor; and
overlaps with an electrical isolation region around the photodiode in the pixel unit in the plan view parallel to the main surface.
